(19) United States
(12) Patent Application Publication
(10) Pub. No.: US 2013/0130424 A1
(43) Pub. Date: May 23, 2013

(54) PROCESS FOR MINIMIZING CHIPPING WHEN SEPARATING MEMS DIES ON A WAFER

(71) Applicants: Roger Horton, Sunnyvale, CA (US); Javed Hussain, Cupertino, CA (US)

(72) Inventors: Roger Horton, Sunnyvale, CA (US); Javed Hussain, Cupertino, CA (US)

(73) Assignee: S3C, INC., Sunnyvale, CA (US)

(21) Appl. No.: 13/695,980

(22) PCT Filed: May 3, 2011
(86) PCT No.: PCT/US2011/035065

§ 371 Date: Dec. 5, 2012

Related U.S. Application Data
(60) Provisional application No. 61/330,767, filed on May 3, 2010.

(51) Int. Cl. H01L 21/78

(52) U.S. Cl. CPC H01L 21/78
USPC 438/50

(57) ABSTRACT

A method for separating a plurality of dies on a Micro-Electro-Mechanical System (MEMS) wafer comprising scribing a notch on a first side of the wafer between at least two of the plurality of dies on a first surface and depositing a metal on the first surface of the plurality of dies. The method further comprises scribing a second side of the wafer between at least two of the plurality of dies from a second surface thereof through the notch. The first side and second side are substantially parallel and opposite each other and the first surface and the second surface are substantially parallel and opposite each other. In a process in accordance with the present invention, a method to minimize chipping of the bonding portion of a MEMs device during sawing of the wafer is provided, which minimally affects the process steps associated with separating the die on a wafer.

### FIELD OF THE INVENTION

The present invention relates generally to MEMS devices and more particularly to separating MEMS dies on a wafer.

### BACKGROUND

A plurality of MEMS dies are typically manufactured in a wafer. The dies are then separated as individual devices via a sawing or dicing process. FIG. 1A illustrates a conventional MEMS wafer 100 before dicing to separate the individual dies 102a and 102b from each other. FIG. 1B illustrates the MEMS wafer 100 of FIG. 1A after dicing the individual dies 102a and 102b.

Referring to FIGS. 1A, each MEMS die 102a and 102b comprises three portions 106a, 108a, 110a and 106b, 108b, 110b, respectively, as shown bonded together using fusion process. Typically, the bottom portion 110a, 110b referred to as a spacer has small area 112 which is bonded to a metal pedestal (not shown). Once process is complete, the wafer 100 is diced into individual dies by sawing from the top as shown at 104 in FIG. 1A.

When the wafer 100 is scribed from the top, the spacer 110 is sometimes chipped (chip outs) 113 enough to reduce the bonding area and causes adhesion problem as shown in FIG. 1B. Current processes for dicing silicon structures, silicon to silicon, silicon to glass structures and any of the structures with metallization applied to the backside or bottom of wafers/substrates results in the bottom edges of the die to have chip outs. These chip outs 113 can affect the 100% formation of a solder bond line fillet that is desired.

Accordingly, what is desired is to provide a system and method that overcomes the above issues. The present invention addresses such a need.

### SUMMARY OF THE INVENTION

A method for separating a plurality of dies on a Micro-Electro-Mechanical System (MEMS) wafer is disclosed. The method comprises scribing a notch on a first side of the wafer between at least two of the plurality of dies on a first surface and depositing a metal on the first surface of the plurality of dies. The method further comprises scribing a second side of the wafer between at least two of the plurality of dies from a second surface thereof through the notch. The first side and second side are substantially parallel and opposite each other and the first surface and the second surface are substantially parallel and opposite each other.

In a process in accordance with the present invention, a method to minimize chipping of the bonding portion of a MEMs device during sawing of the wafer is provided. This process minimally affects the process steps associated with separating the die on a wafer.

Other aspects and advantages of the present invention will become apparent from the following detailed description, taken in conjunction with the accompanying drawings, illustrating by way of example the principles of the invention.

### BRIEF DESCRIPTION OF THE DRAWINGS

FIG. 1A illustrates a conventional MEMS wafer before dicing to separate the individual dies from each other.

FIG. 1B illustrates the MEMS wafer of FIG. 1A after dicing the individual dies.

FIG. 2 shows a flow chart of a process of separating dies on a wafer in accordance with the present invention.

FIG. 3A-3C illustrates a dicing in accordance with the present invention.

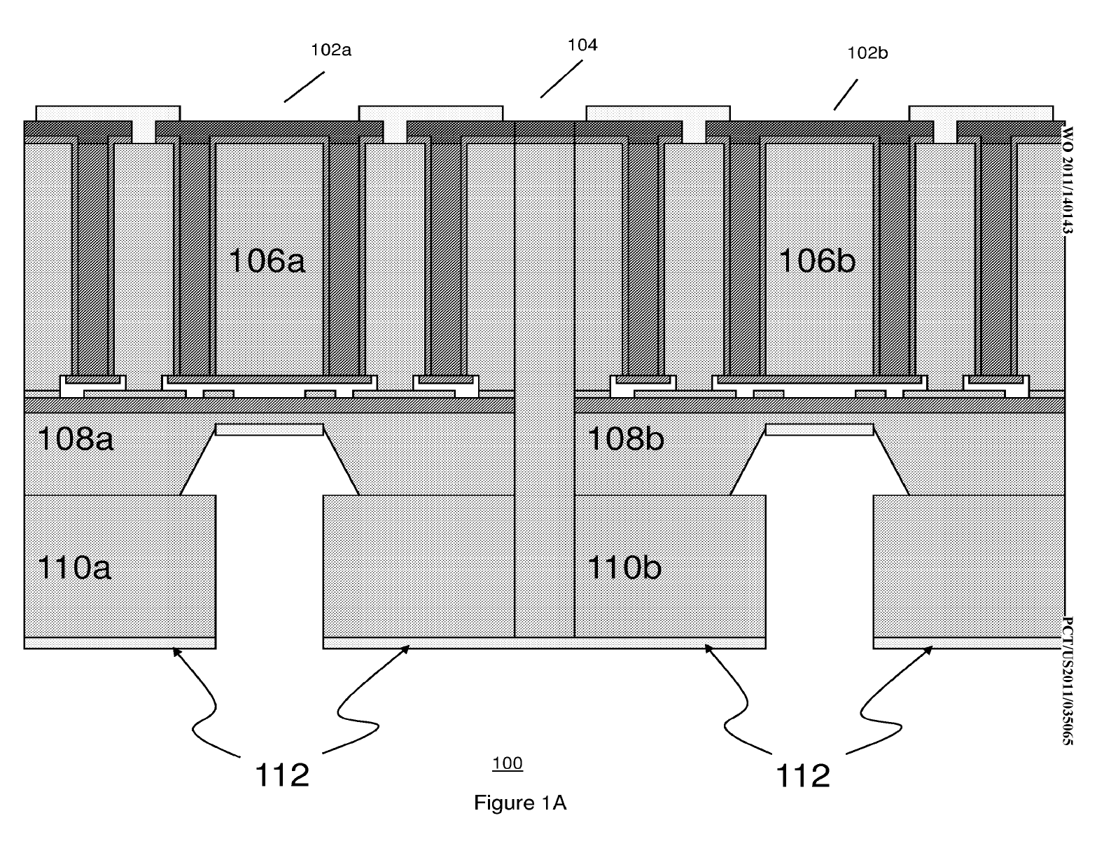

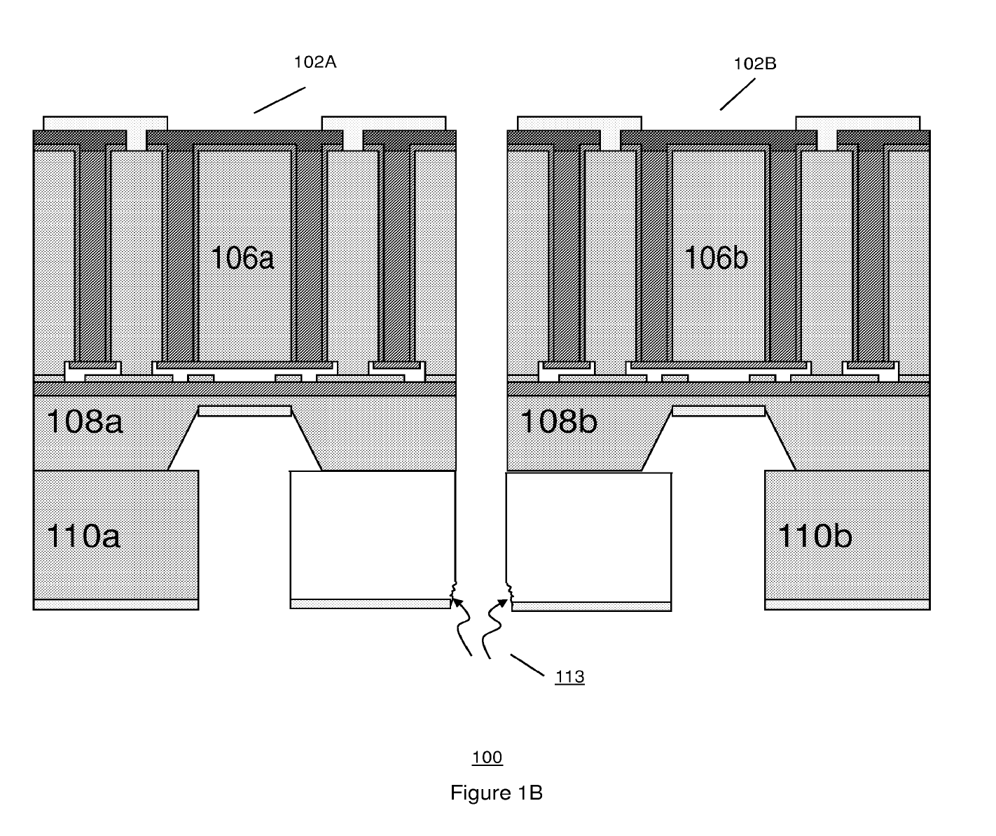

### DETAILED DESCRIPTION OF PREFERRED EMBODIMENTS

The following description is presented to enable one of ordinary skill in the art to make and use the invention and is provided in the context of a patent application and its requirements. Various modifications to the preferred embodiment and the generic principles and features described herein will be readily apparent to those skilled in the art. Thus, the present invention is not intended to be limited to the embodiment shown but is to be accorded the widest scope consistent with the principles and features described herein.

Reference will now be made in detail to implementations of the example embodiments as illustrated in the accompanying drawings. The same reference indicators will be used throughout the drawings and the following description to refer to the same or like items.

In accordance with this disclosure, the components and process steps described herein may be implemented using various types of semiconductor manufacturing equipment. It is understood that the phrase “an embodiment” encompasses more than one embodiment and is thus not limited to only one embodiment.

Embodiments of the present invention can be utilized with pressure sensors that can be used for a wide range of temperature and pressure, including automobile applications. Persons skilled in the art will appreciate that similar processes may be used to make other type of MEMs devices. Although silicon is often shown as the material of choice for making a micromachined device the invention is not limited by the choice of material.

In a process in accordance with the present invention, a method to minimize chipping of the bonding portion of a MEMs device during sawing of the wafer is provided. This process minimally affects the process steps associated with separating the die on a wafer. To more particularly describe the features of the present invention in more detail refer now to the following description in conjunction with the accompanying figures.

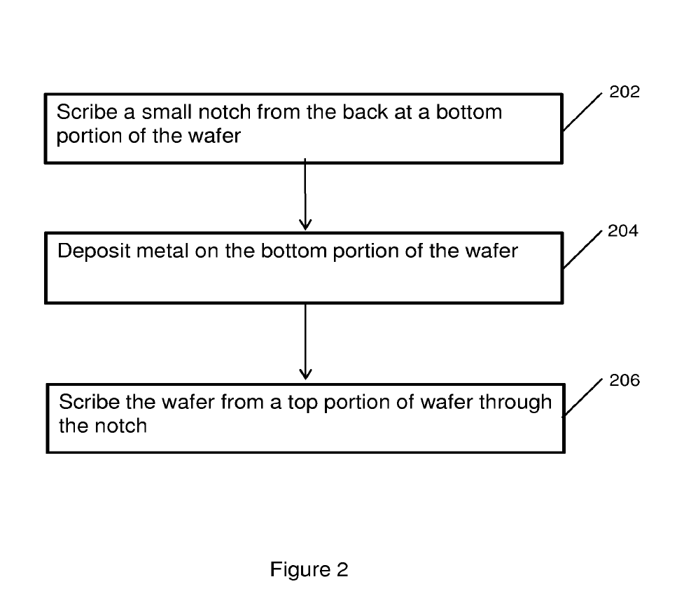

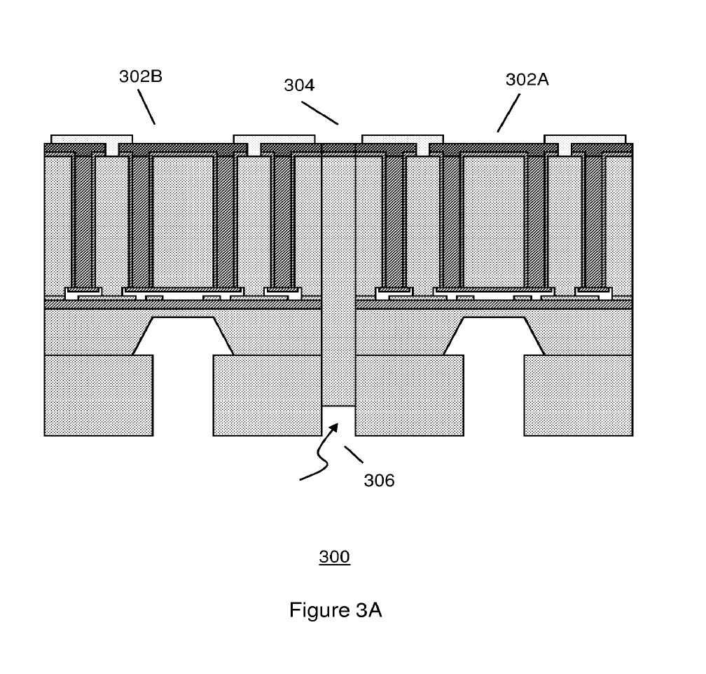

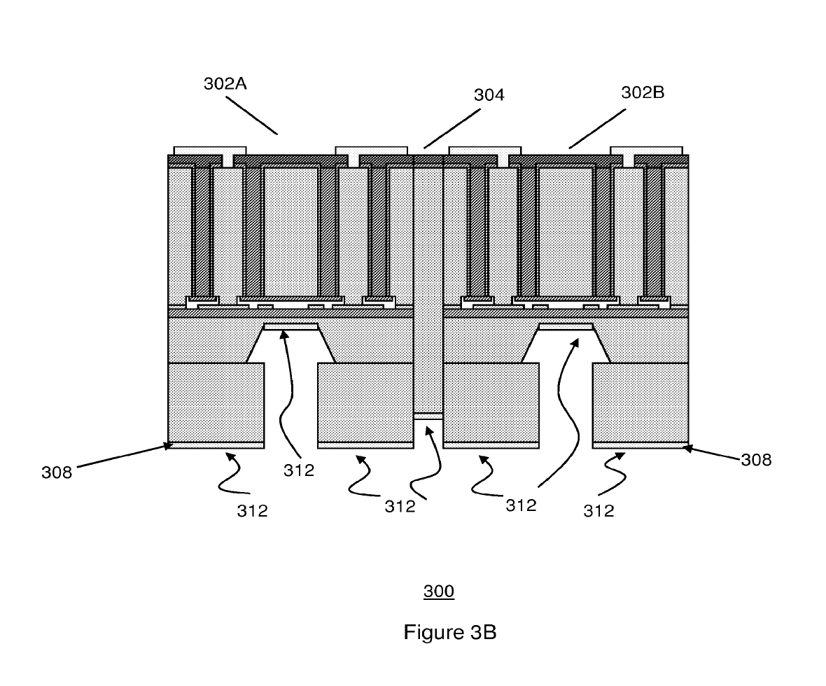

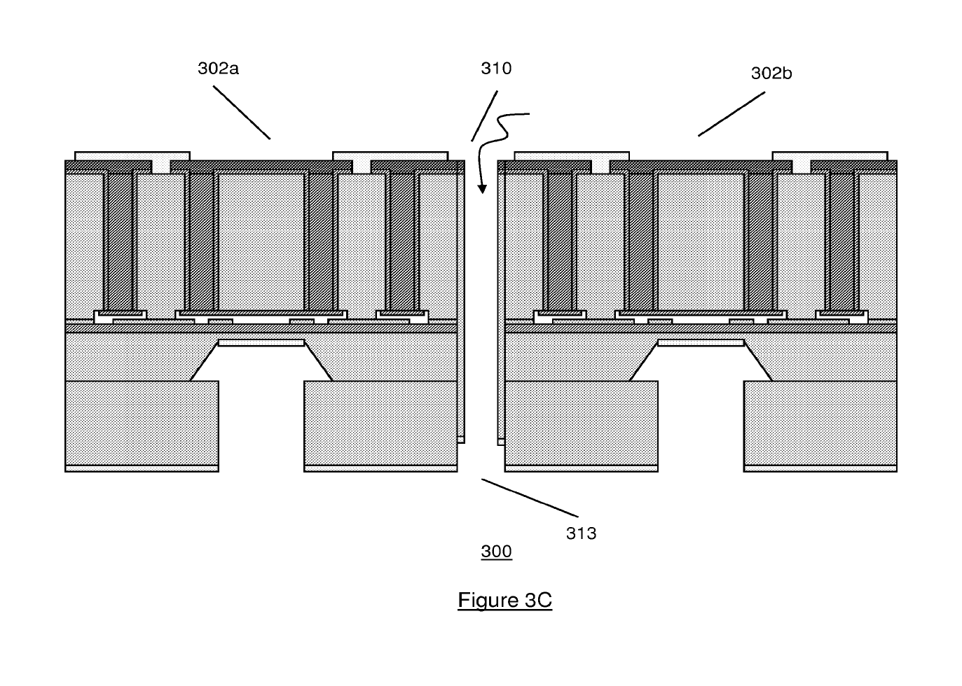

FIG. 2 shows a flow chart of a process of separating dies on a wafer in accordance with the present invention. FIG. 3A-3C illustrates a separating a wafer 300 into a plurality of dies 302a-302b in accordance with the present invention. It is well understood by one of ordinary skill in the art that although only two die are shown on the wafer 300, there are normally many dies on one wafer and they are not limited to only two. Referring to FIGS. 2 and 3A-3C together, firstly, a small notch 306 (shown in FIG. 3A) is scribed from the back of the wafer 300 (approximately 10% of the wafer height) between the two dies 302a and 302b, via step 202. Then a metal 308, such as Ti/Pt/Au is deposited at a bottom surface 312 (shown in FIG. 3B) of the wafer 300, via step 204, which then fills any chipped area. Thereafter, the wafer 300 is scribed on a front side of the wafer from a top surface 310 (shown in FIG. 3C) of the wafer 300 through the notch 306, via step 206. In an embodiment, the saw that is utilized for dicing the notch 306 is wider than the saw utilized for the front side dicing to allow for an undercut ledge 313.

A method and system in accordance with the present invention aides in the ability of the solder to achieve a true fillet shape formation at the bond line edge of a die. By allowing metallization up the sides of the undercut, solder wicking up the outside die sides is enhanced and a solder fillet is formed at the bond line. Furthermore, through the use of a process in accordance with the present invention the height of vertical wicking of the solder is controlled by use of the undercut ledge 313.

Although the present invention has been described in accordance with the embodiments shown, one of ordinary skill in the art will readily recognize that there could be variations to the embodiments and those variations would be within the spirit and scope of the present invention. Accordingly, many modifications may be made by one of ordinary skill in the art without departing from the spirit and scope of the appended claims.

What is claimed is:

1. A method for separating a plurality of dies on a Micro-Electro-Mechanical System (MEMS) wafer, comprising:
scribing a notch on a first side of the wafer between at least two of the plurality of dies on a first surface;
depositing a metal on the first surface of the plurality of dies;
scribing a second side of the wafer between at least two of the plurality of dies from a second surface thereof through the notch; wherein the first side and second side are substantially parallel and opposite each other and the first surface and the second surface are substantially parallel and opposite each other.

2. The method of claim 1, wherein a saw that is utilized for scribing the notch is wider than the saw utilized for scribing the second side of the wafer to provide an undercut ledge on each of the die.

3. The method of claim 1 wherein the first side comprises a back side of the wafer and the second side comprises the front side of the wafer.

4. The method of claim 1 wherein the first surface comprises a bottom surface and the second surface comprises a top surface.

5. The method of claim 1 wherein the metal comprises Ti/Pt/Au.

6. A method for separating a plurality of dies on a Micro-Electro-Mechanical System (MEMS) wafer, comprising:
scribing a notch on a back side of the wafer between at least two of the plurality of dies on a bottom surface;
depositing a metal on the bottom surface of the plurality of dies; and
scribing a front side of the wafer between at least two of the plurality of dies from a top surface thereof through the notch; wherein a saw that is utilized for scribing the notch is wider than the saw utilized for scribing the front side of the wafer to provide an undercut ledge on each of the die.
